(19) United States
(12) Patent Application Publication
(10) Pub. No.: US 2024/0397701 A1
(43) Pub. Date: Nov. 28, 2024

(54) SEMICONDUCTOR DEVICES

(71) Applicant: Samsung Electronics Co., Ltd., Suwon-si (KR)

(72) Inventors: Taejin Park, Suwon-si (KR); Taejin Kim, Suwon-si (KR); Sungsoo Yim, Suwon-si (KR)

(21) Appl. No.: 18/637,580

(22) Filed: Apr. 17, 2024

(30) Foreign Application Priority Data
May 22, 2023 (KR) 10-2023-0065721

(51) Int. Cl. H10B 12/00

(52) U.S. Cl. CPC H10B 12/315; H10B 12/05; H10B 12/482; H10B 12/50

(57) ABSTRACT

A semiconductor device may include a bit line on a substrate, a bonding layer stacked on the bit line, a first conductive connection pattern stacked on the bonding structure layer, so that the bonding layer is vertically between the bit line and the first conductive layer, a channel stacked on the first conductive connection pattern and including a single crystalline semiconductor material, a second conductive connection pattern contacting the bit line and the first conductive connection pattern, a gate electrode on the bit line and being spaced apart from the channel and the first conductive connection pattern, and a capacitor stacked on the channel.

### CROSS-REFERENCE TO RELATED APPLICATION

This application claims priority under 35 U.S.C. § 119 to Korean Patent Application No. 10-2023-0065721 filed on May 22, 2023 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a memory device including a vertical channel.

### DISCUSSION OF RELATED ART

In order to improve an integration degree of a semiconductor device, a memory device including a vertical channel transistor has been developed, and recently, an oxide semiconductor material has been used in a channel of the vertical channel transistor. However, a chemical reduction of the oxide semiconductor material occurs at a low energy level, and many oxygen vacancies are generated. In order to overcome the disadvantage of the oxide semiconductor channel, a method of manufacturing a vertical channel transistor including a single crystalline silicon channel is desired.

### SUMMARY

Example embodiments provide a semiconductor device having improved characteristics.

According to example embodiments a semiconductor device may include a bit line on a substrate, a bonding layer stacked on the bit line, a first conductive connection pattern stacked on the bonding structure layer, so that the bonding layer is vertically between the bit line and the first conductive layer, a channel stacked on the first conductive connection pattern and including a single crystalline semiconductor material, a second conductive connection pattern contacting the bit line and the first conductive connection pattern, a gate electrode on the bit line and being spaced apart from the channel and the first conductive connection pattern, and a capacitor stacked on the channel.

According to example embodiments, a semiconductor device may include a bit line on a substrate, an insulative bonding layer stacked on the bit line, a first source/drain pattern stacked on the bonding layer, so that the bonding layer is between the bit line and the first source/drain pattern, the first source/drain pattern including doped polysilicon, a channel on the first source/drain pattern and including a single crystalline semiconductor material, a conductive pattern vertically between the channel and the bonding layer, a conductive connection pattern contacting the bit line and the conductive pattern, a gate electrode on the bit line and being spaced apart from the channel and the conductive pattern, and a capacitor on the channel.

According to example embodiments, a semiconductor device may include a lower circuit pattern on a substrate, bit lines on the lower circuit pattern, each of the bit lines extending in a first direction parallel to an upper surface of the substrate, and the bit lines being spaced apart from each other in a second direction parallel to the upper surface of the substrate and crossing the first direction, bonding structures on the bit lines, respectively, a plurality of first conductive connection patterns, each first conductive connection pattern on a respective bonding structure, a plurality of first source/drain patterns, each first source/drain pattern on a respective first conductive connection pattern, a plurality of channels, each channel on a respective first source/drain pattern, a plurality of second conductive connection patterns, each second conductive connection pattern contacting a respective bit line of the bit lines and a respective first conductive pattern of the plurality of first conductive connection patterns, a plurality of gate electrodes, each gate electrode on a respective bit line, each of the gate electrodes extending in the second direction, and the gate electrodes being spaced apart from each other in the first direction, a gate insulation pattern on a sidewall of each of the gate electrodes and contacting each of the channels, a plurality of second source/drain patterns, each second source/drain pattern on a respective channel, a plurality of landing pads, each landing pad on a respective second source/drain pattern; and a plurality of capacitors, each capacitor on a respective landing pad.

In the method of manufacturing the semiconductor device in accordance with example embodiments, the bit line may be directly formed on the transistor on the substrate, and thus misalignment may not occur between the bit line and the transistor. Accordingly, an additional pad for complementing the misalignment is not needed, so that the semiconductor device may have an enhanced integration degree.

### BRIEF DESCRIPTION OF THE DRAWINGS

FIGS. 1 to 3 are a plan view and cross-sectional views illustrating a semiconductor device in accordance with example embodiments.

FIGS. 4 to 22 are plan views and cross-sectional views illustrating a method of manufacturing a semiconductor device in accordance with example embodiments.

FIGS. 23 and 24 are a plan view and a cross-sectional view illustrating a semiconductor device in accordance with example embodiments.

FIGS. 25 to 28 are cross-sectional views illustrating a method of manufacturing a semiconductor device in accordance with example embodiments.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In example embodiments, the first and second directions D1 and D2 may be orthogonal to each other.

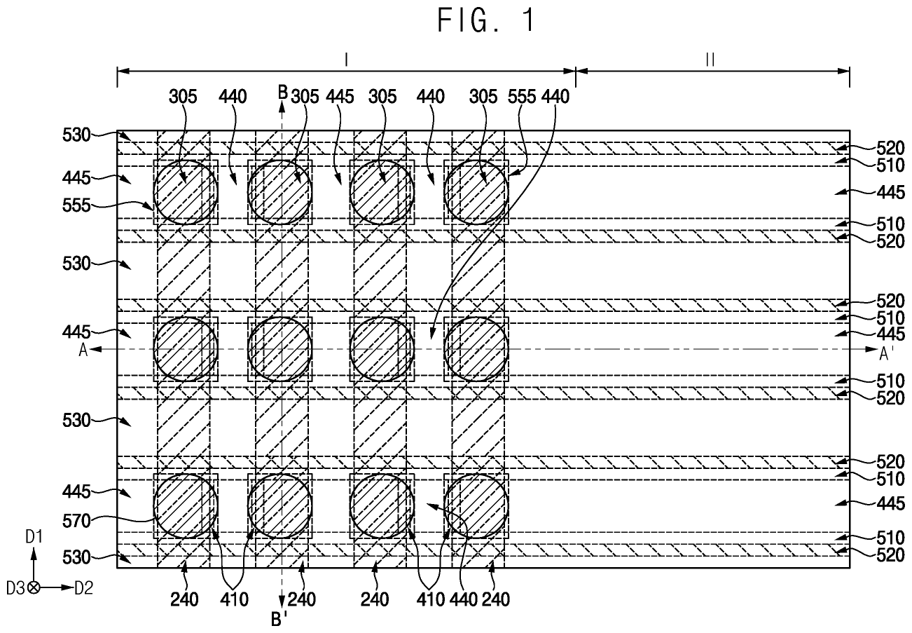

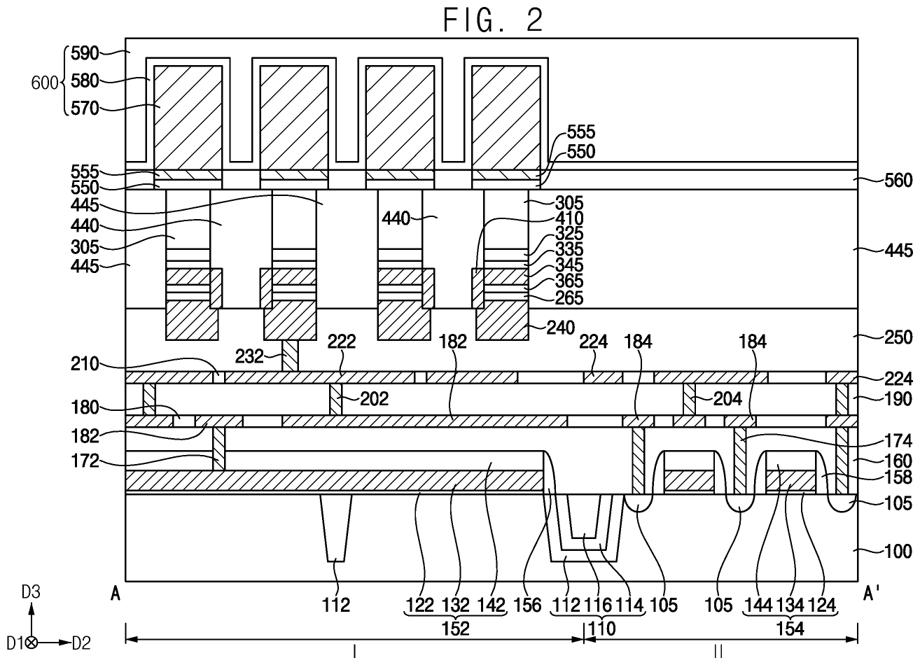

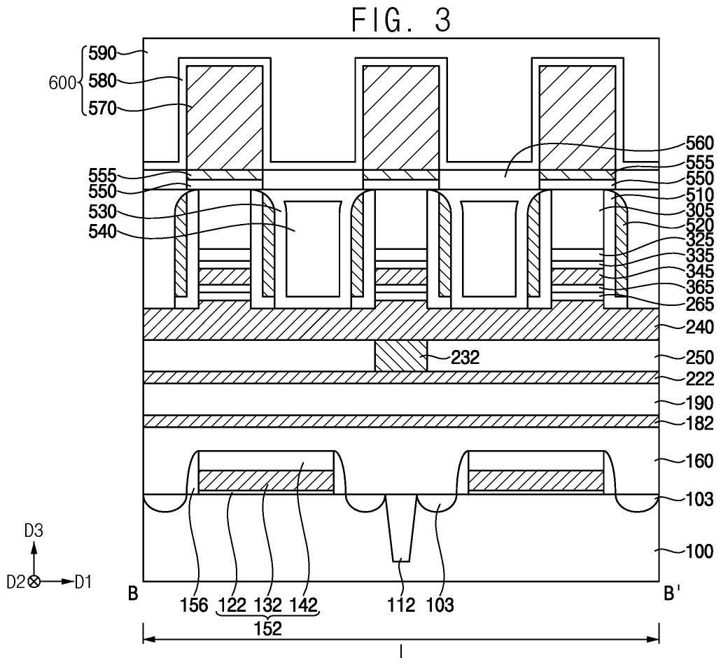

FIGS. 1 to 3 are a plan view and cross-sectional views illustrating a semiconductor device in accordance with example embodiments. Specifically, FIG. 1 is the plan view, FIG. 2 is a cross-sectional view taken along line A-A′ of FIG. 1, and FIG. 3 is a cross-sectional view taken along line B-B′ of FIG. 1. For example, the semiconductor device may be a semiconductor memory device such as a semiconductor memory die formed as a semiconductor chip from a wafer.

Referring to FIGS. 1 to 3, the semiconductor device may include a lower circuit pattern, a bit line 240, a bonding structure, first and second connection patterns 345 and 410, a channel 305, first and second source/drain patterns 325 and 550, a first ohmic pattern 335, a third gate electrode 520, a third gate insulation pattern 510, a landing pad 555 and a capacitor 600 on a first substrate 100.

The semiconductor device may further include first to seventh insulating interlayers 160, 180, 190, 210, 250, 440 and 445, eighth and ninth insulating interlayer patterns 540 and 560 and a first insulation pattern 530.

The first substrate 100 may include or be formed of silicon, germanium, silicon-germanium, or a III-V group compound semiconductor, e.g., GaP, GaAs, GaSb, etc. In example embodiments, the first substrate 100 may be a silicon-on-insulator (SOI) substrate or a germanium-on-insulator (GOI) substrate.

The first substrate 100 may include first and second regions I and II, and the second region II may surround the first region I. The first region I may be a cell array region in which memory cells are formed and the second region II may be a peripheral circuit region in which peripheral circuit patterns for applying electrical signals to the memory cells are formed.

The semiconductor device may have a cell over periphery (COP) structure in which the memory cells are disposed over the peripheral circuit patterns.

An isolation structure 110 may be formed on the first substrate 100, and the isolation structure 110 may include some or all of first, second and third isolation patterns 112, 114 and 116. For example, a portion of the isolation structure 110 at a boundary between the first and second regions I and II of the first substrate 100 may include all of the first to third isolation patterns 112, 114 and 116, while a portion of the isolation structure 110 on each of the first and second regions I and II of the first substrate 100 may include only the first isolation pattern 112, however, the inventive concept may not be limited thereto.

Each of the first and third isolation patterns 112 and 116 may include or be formed of an oxide, e.g., silicon oxide, and the second isolation pattern 114 may include or be formed of an insulating nitride, e.g., silicon nitride.

The lower circuit pattern may include transistors, and FIGS. 1 to 3 shows first and second transistors. The lower circuit pattern may further include contact plugs and wirings.

The first transistor may include a first gate structure 152 and a first impurity region 103 on the first region I of the first substrate 100, and the second transistor may include a second gate structure 154 and a second impurity region 105 on the second region II of the first substrate 100. Though certain components may be described in the singular, they may be provided in plural, as can be seen from the drawings and as would be evident from the context in which they are described. For example, a plurality of first transistors and plurality of second transistors may be included.

The first gate structure 152 may include a first gate insulation pattern 122, a first gate electrode 132 and a first gate mask 142 sequentially stacked in the third direction D3, the second gate structure 154 may include a second gate insulation pattern 124, a second gate electrode 134 and a second gate mask 144 sequentially stacked in the third direction D3. A first gate spacer 156 may be formed on each of opposite sidewalls of the first gate structure 152, and a second gate spacer 158 may be formed on each of opposite sidewalls of the second gate structure 154.

The first insulating interlayer 160 may be formed on the first substrate 100, and may cover the first and second transistors and the first and second gate spacers 156 and 158.

A first contact plug 172 may extend through the first insulating interlayer 160 and the first gate mask 142, and may contact an upper surface of the first gate electrode 132. The second contact plug 174 may extend through the first insulating interlayer 160, and may contact an upper surface of the second impurity region 105. A third contact plug (not shown) may extend through the first insulating interlayer 160, and may contact an upper surface of the first impurities region 103. A fourth contact plug (not shown) may extend through the first insulating interlayer 160 and the second gate mask 144, and may contact an upper surface of the second gate electrode 134.

The second insulating interlayer 180 may be formed on the first insulating interlayer 160, the first and second contact plugs 172 and 174 and the third and fourth contact plugs. First and second wirings 182 and 184 may extend through the second insulating interlayer 180, and may contact upper surface of the first and second contact plugs 172 and 174, respectively.

The third insulating interlayer 190 may be formed on the second insulating interlayer 180 and the first and second wirings 182 and 184. Fifth and sixth contact plugs 202 and 204 may extend through the third insulating interlayer 190, and may contact upper surfaces of the first and second wirings 182 and 184, respectively.

The fourth insulating interlayer 210 may be formed on the third insulating interlayer 190 and the fifth and sixth contact plugs 202 and 204. Third and fourth wirings 222 and 224 may extend through the fourth insulating interlayer 210, and may contact upper surfaces of the fifth and sixth contact plugs 202 and 204, respectively.

The fifth insulating interlayer 250 may be formed on the fourth insulating interlayer 210 and the third and fourth wirings 222 and 224. A seventh contact plug 232 may extend through a lower portion of the fifth insulating interlayer 250, and may contact an upper surface of the third wiring 222. The various insulating interlayers may be formed, for example, of an insulating material such as silicon oxide.

The bit line 240 may extend through an upper portion of the fifth insulating interlayer 250 in the first direction D1 on the first region I of the first substrate 100 and a portion of the second region II of the first substrate 100 adjacent to the first region I of the first substrate 100 in the first direction D1.

Hereinafter, two bit lines 240 adjacent to each other in the second direction D2 may be referred to as a bit line pair. In example embodiments, a plurality of bit line pairs may be disposed in the second direction D2 and may each extend in the first direction D1.

In an example embodiment, the bit line 240 may include or be formed of a metal or a metal nitride. Alternatively, the bit line 240 may have a multi-layered structure having a first pattern including a metal or a metal nitride and a second pattern including doped polysilicon. Alternatively, the bit line 240 may include or be formed of doped polysilicon. Hereinafter, only a case in which the bit line 240 is formed of a metal or a metal nitride is illustrated.

The bonding structure may include first and second bonding patterns 265 and 365 stacked in the third direction D3. For each vertical channel transistor (including a capacitor 600, channel 305, and connecting elements between the capacitor 600 and channel 305 and between the channel 305 and a bit line 240), the bonding structure including the first and second bonding patterns 265 and 365 stacked in the third direction D3 may be described as a bonding layer, which may include one or more layers of insulative material bonded to each other, and which help adhere the bit line 240 to the first connection pattern 345. This bonding layer may also be referred to as a bonding pad, for example, an insulative bonding pad. In example embodiments, a plurality of bonding structures may be spaced apart from each other in the first direction D1 on each of the bit lines 240. As a plurality of bit lines 240 are spaced apart from each other in the second direction D2, a plurality of bonding structures may be spaced apart from each other in each of the first and second directions D1 and D2. Each of the first and second bonding patterns 265 and 365 may include or be formed of, e.g., silicon carbonitride, however, the inventive concept may not be limited thereto.

The first conductive connection patterns 345 may be respectively formed on each of the bonding structures, and thus a plurality of first conductive connection patterns 345 may be spaced apart from each other in each of the first and second directions D1 and D2. The first conductive connection pattern 345 may include or be formed of, e.g., a metal, a metal nitride, etc.

The second conductive connection patterns 410 may respectively contact an upper surface of each bit line 240 and sidewalls of the bonding structure and the first conductive connection pattern 345, and a plurality of second conductive connection patterns 410 may be spaced apart from each other in each of the first and second directions D1 and D2. In example embodiments, the second conductive connection pattern 410 may be disposed on each of facing sidewalls in the second direction D2 of respective two bit lines 240 of each bit line pair. For example, for each bit line pair, a first sidewall of a first bit line faces a second sidewall of a second bit line, one second conductive connection 410 pattern is disposed on a first sidewall of the first bit line, and another second conductive connection pattern 410 is disposed on a second sidewall of the second bit line.

In an example embodiment, an outer sidewall of the second conductive connection pattern 410 may protrude in the second direction D2 beyond a sidewall of the bit line 240 contacting the second conductive connection pattern 410. However, the inventive concept may not be limited thereto, and the outer sidewall of the second conductive connection pattern 410 may be aligned in the third direction D3 with (e.g., to be coplanar with) the sidewall of the bit line 240 contacting the second conductive connection pattern 410. The second conductive connection pattern 410 may be formed in a recess in the sixth insulating interlayer 440, to have a length in the first direction D1 the same as a width of the sixth insulating interlayer 440 in the first direction. A bottom of the second conductive pattern 410 may be formed in a recessed corner portion of the bit line 240 at a top of the bit line 240. The second conductive pattern 410 may have a shape in which sidewalls formed on a plane formed parallel to the D1 and D3 directions have a greater area than sidewalls formed on a plane formed parallel to the D2 and D3 directions, and have a greater area than top and bottom surfaces formed on a plane formed parallel to the D1 and D2 directions.

In example embodiments, an upper surface of the second conductive connection pattern 410 may be higher than a lower surface of the first conductive connection pattern 345, and may be lower than an upper surface of the first source/drain pattern 325. In an example embodiment, the upper surface of the second conductive connection pattern 410 may be lower than a lower surface of the first source/drain pattern 325. Alternatively, the upper surface of the second conductive connection pattern 410 may be substantially coplanar with a lower surface of the first ohmic contact pattern 335, which is shown in FIG. 2. Terms such as higher and lower are described herein with respect to a top surface of the substrate 100, and refer to a height in the D3 direction, unless noted otherwise. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The second conductive connection pattern 410 may include or be formed of, e.g., a metal, a metal nitride, etc. In an example embodiment, the second conductive connection pattern 410 may include or be formed of a material substantially the same as a material of the first conductive connection pattern 345 and the bit line 240, and thus may be merged thereto. The second conductive pattern 410 may extend vertically to electrically connect the bit line 240 to the first conductive connection pattern 345.

The first ohmic contact pattern 335 may be disposed on the first conductive connection pattern 345, and a plurality of first ohmic contact patterns 345 may be spaced apart from each other in the first and second directions D1 and D2. In an example embodiment, the first ohmic contact pattern 335 may include or be formed of silicide of a metal included in the first conductive connection pattern 345. Alternatively, the first ohmic contact pattern 335 may include or be formed of silicide of another metal that is not included in the first conductive connection pattern 345.

If the bit line 240 is formed of doped polysilicon or has a multi-layered structure, each of the first and second conductive connection patterns 345 and 410 may be formed of doped polysilicon, and in this case, the first ohmic contact pattern 335 may not be formed.

The first source/drain pattern 325 may be disposed on the first conductive connection pattern 345, and a plurality of first source/drain patterns 325 may be spaced apart from each other in the first and second directions D1 and D2. The first source/drain pattern 325 may include or be formed of, e.g., polysilicon doped with n-type impurities or p-type impurities.

The channel 305 may be disposed on the first source/drain pattern 325, and a plurality of channels 305 may be spaced apart from each other in the first and second directions D1 and D2. In example embodiments, the channel 305 may include or be formed of a single crystalline semiconductor material, e.g., single crystalline silicon, single crystalline germanium, single crystalline silicon-germanium, etc.

In example embodiments, a sidewall on a plane formed parallel to in the first and third directions D1 and D3 second direction D2 of the channel 305 may be aligned in the third direction D3 with an inner sidewall of the second conductive connection pattern 410.

The third gate insulation pattern 510 may extend in the D2 direction on the bit lines 240 and the fifth insulating interlayer 250, and a plurality of third gate insulation patterns 510 may be spaced apart from each other in the first direction D1. The third gate insulation pattern 510 may contact sidewalls in the first direction D1 of the bonding structure, the first conductive connection pattern 345, the first ohmic contact pattern 335, the first source/drain pattern 325 and the channel 305, and a cross-section of the third gate insulation pattern 510 as viewed from the second direction D2 may have a shape of an “L.” The third gate insulation pattern 510 may include or be formed of a metal oxide, e.g., silicon oxide. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The third gate electrode 520 may be disposed on the third gate insulation pattern 510. Thus, the third gate electrode 520 may extend in the second direction D2, and a plurality of third gate electrodes 520 may be spaced apart from each other in the first direction D1. The third gate electrode 520 may include or be formed of, e.g., a metal, a metal nitride, doped polysilicon, etc.

The eighth insulating interlayer pattern 540 may include portions extending in the second direction D2 on the bit lines 240 and the fifth insulating interlayer 250 between neighboring ones of the third gate electrodes 520 in the first direction D1, and the first insulation pattern 530 may cover upper and lower surfaces and a sidewall in the first direction D1 of the eighth insulating interlayer pattern 540. The first insulation pattern 530 may contact upper surfaces of the bit lines 240 and the fifth insulating interlayer 250, a sidewall in the first direction D1 and an upper surface of the third gate electrode 520 and a sidewall in the first direction D1 of the third gate insulation pattern 510.

In example embodiments, an upper surface of the first insulation pattern 530 may be substantially coplanar with an upper surface of the channel 305.

In an example embodiment, the eighth insulating interlayer pattern 540 may include or be formed of an oxide, e.g., silicon oxide, and the first insulation pattern 530 may include or be formed of an insulating nitride, e.g., silicon nitride, however, the inventive concept may not be limited thereto.

The sixth and seventh insulating interlayers 440 and 445 may be alternately and repeatedly disposed on the fifth insulating interlayer 250. In example embodiments, the sixth insulating interlayer 440 may be disposed between the two bit lines 240 of each bit line pair, and may cover the second conductive connection patterns 410. The seventh insulating interlayer 445 may be disposed between neighboring ones of the bit line pairs in the second direction D2. An upper surface of each of the sixth and seventh insulating interlayers 440 and 445 may be substantially coplanar with the upper surface of the channel 305.

Each of the sixth and seventh insulating interlayers 440 and 445 may include or be formed of an oxide, e.g., silicon oxide.

The ninth insulating interlayer pattern 560 may be disposed on the sixth and seventh insulating interlayers 440 and 445, the channel 305 and the first insulation pattern 530. The second source/drain pattern 550 may extend through the ninth insulating interlayer pattern 560, and may contact the upper surface of the channel 305. In example embodiments, a plurality of second source/drain patterns 550 may be spaced apart from each other in the first and second directions D1 and D2.

The ninth insulating interlayer pattern 560 may include or be formed of an oxide, e.g., silicon oxide, and the second source/drain pattern 550 may include or be formed of polysilicon doped with n-type impurities or p-type impurities. In example embodiments, the second source/drain pattern 550 may include impurities having the same conductivity type as the first source/drain pattern 325.

The landing pad 555 may be disposed on the second source/drain pattern 550, and a plurality of landing pads 555 may be spaced apart from each other in the first and second directions D1 and D2. The landing pads 555 may be arranged in a lattice pattern or a honeycomb pattern in a plan view. The landing pad 555 may include or be formed of, e.g., a metal, a metal nitride, doped polysilicon, etc.

The capacitor 600 may include first and second capacitor electrodes 570 and 590 and a dielectric layer 580. The first capacitor electrode 570 may be disposed on the landing pad 555, the dielectric layer 580 may be disposed on an upper surface and a sidewall of the first capacitor electrode 570 and an upper surface of the ninth insulating interlayer pattern 560, and the second capacitor electrode 590 may be disposed on the dielectric layer 580.

As the landing pads 555 are spaced apart from each other in the first and second direction D1 and D2, a plurality of first capacitor electrodes 570 may be spaced apart from each other in the first and second directions D1 and D2. In example embodiments, the first capacitor electrode 570 may have a shape of, e.g., a circle, an ellipse, a polygon, a polygon with rounded corners, etc., in a plan view. The first capacitor electrodes 570 may be arranged in a lattice pattern or a honeycomb pattern in a plan view.

In the semiconductor device, current may flow in the channel 305 between the bit line 240 and the landing pad 555 in the third direction D3, that is, in the vertical direction, and thus the semiconductor device may include a vertical channel transistor (VCT) having a vertical channel.

As illustrated above, the channel 305 may include or be formed of single crystalline silicon, and thus may have enhanced electrical characteristics when compared to a channel including polysilicon or an oxide semiconductor material. The channel 305 and the bit line 240 may be electrically connected to each other through the first and second conductive connection patterns 345 and 410, which may be well-connected to the channel 305 and the bit line 240, as illustrated below.

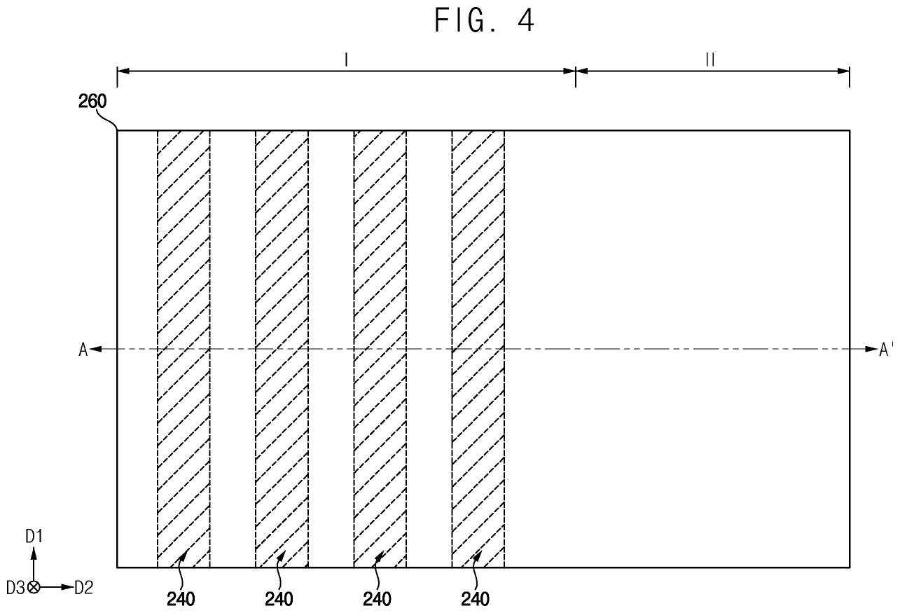

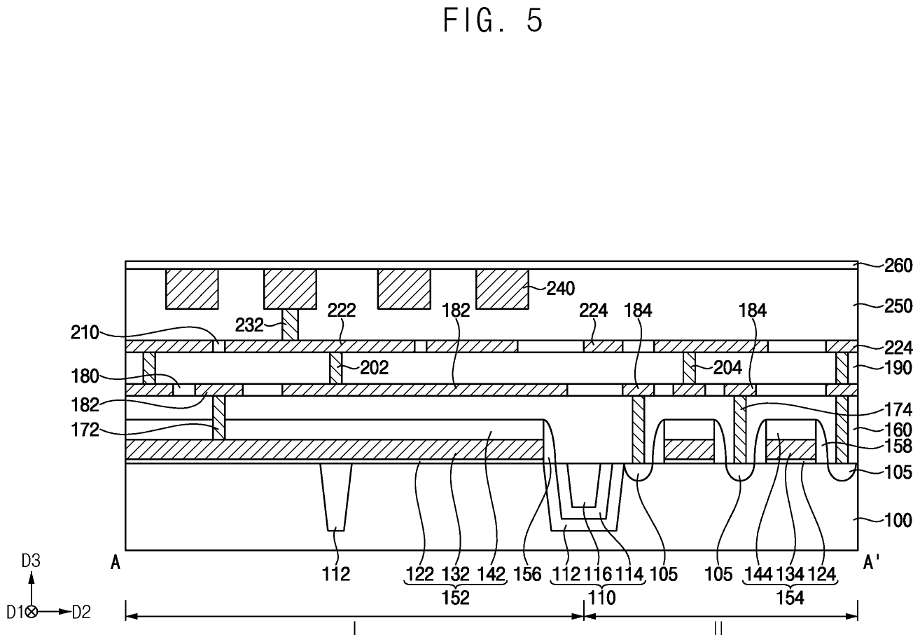

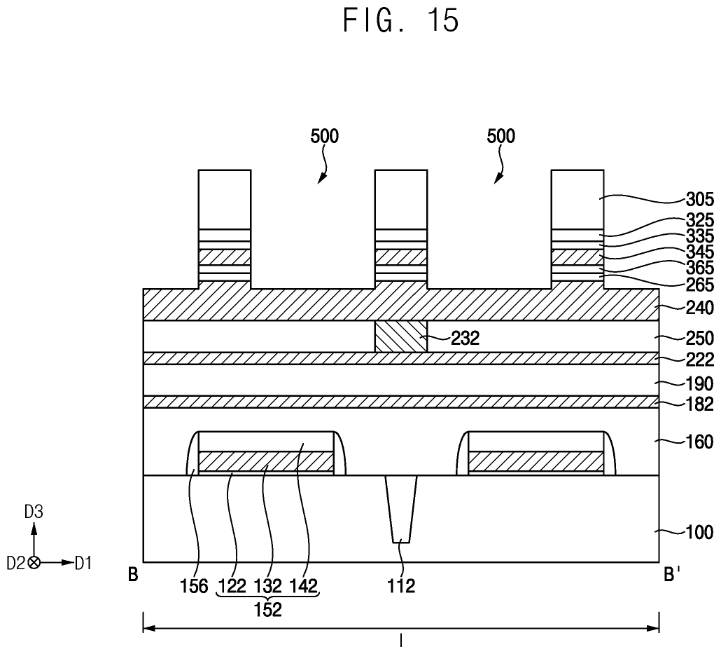

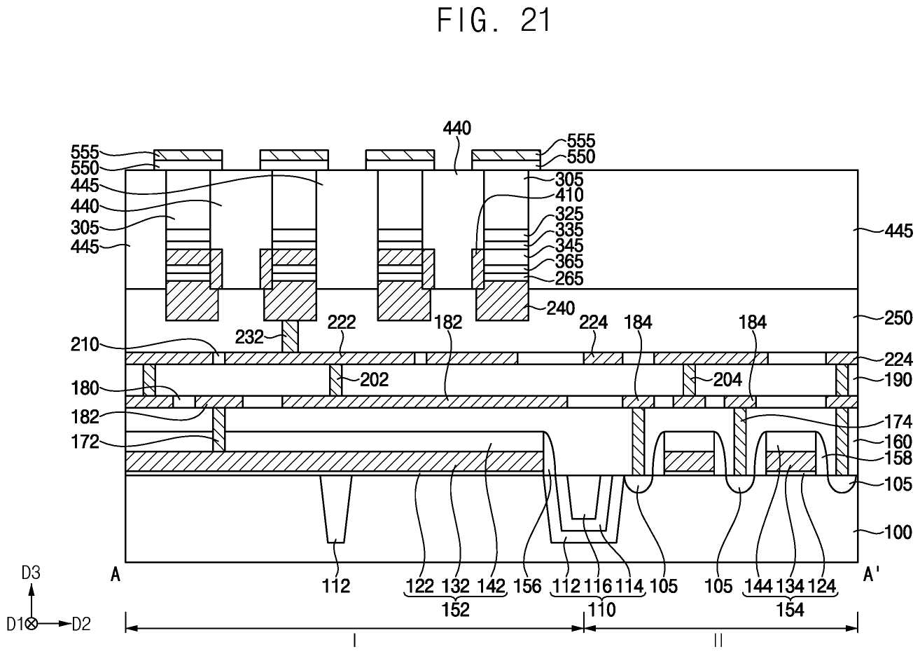

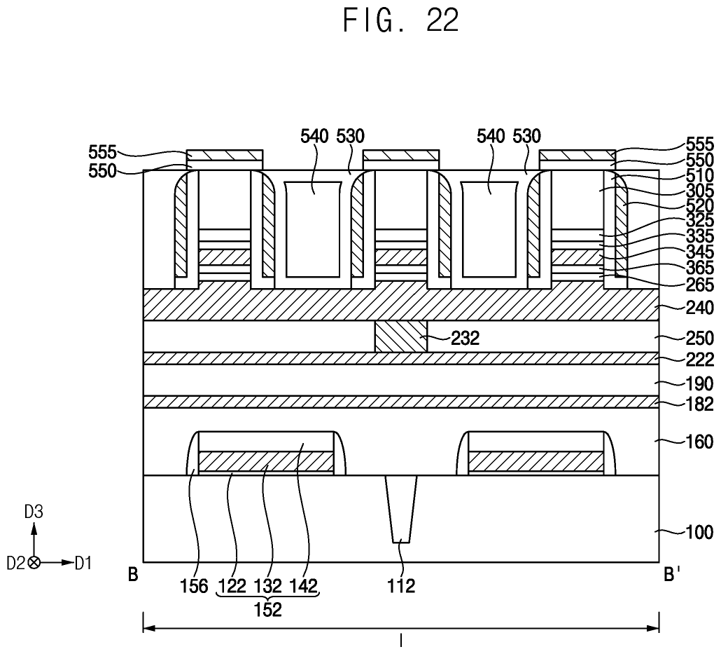

FIGS. 4 to 22 are plan views and cross-sectional views illustrating a method of manufacturing a semiconductor device in accordance with example embodiments. Specifically, FIGS. 4, 7, 10, 12, 14, 16, 18 and 20 are the plan views, FIGS. 5, 6, 8, 9, 11, 13 and 21 are cross-sectional views taken along lines A-A′ of corresponding plan views, respectively, and FIGS. 15, 17, 19 and 22 are cross-sectional views taken along lines B-B′ of corresponding plan views, respectively.

Referring to FIGS. 4 and 5, a lower circuit pattern, a plurality of bit lines 240 and first to fifth insulating interlayers 160, 180, 190, 210 and 250 may be formed on a first substrate 100 including first and second regions I and II.

The bit lines 240 may extend through an upper portion of the fifth insulating interlayer 250, and may extend on the first region I of the first substrate 100 and a portion of the second region II of the first substrate 100 adjacent to the first region I of the first substrate 100 in the first direction D1. In example embodiments, the bit lines 240 may be spaced apart from each other in the second direction D2.

A first bonding layer 260 may be formed on the bit lines 240 and the fifth insulating interlayer 250 on the first and second regions I and II of the first substrate 100.

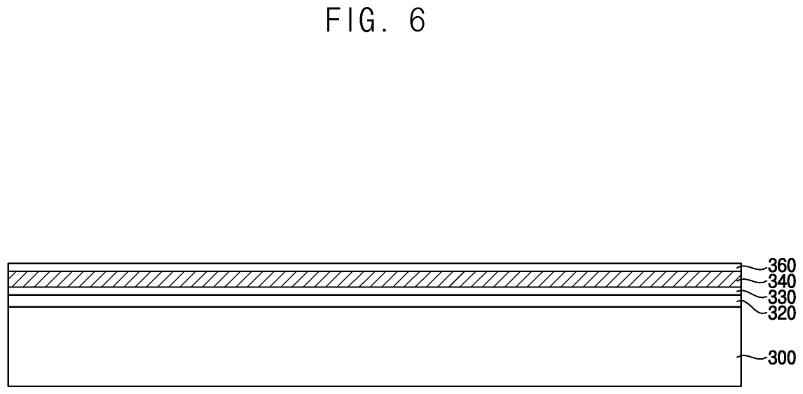

Referring to FIG. 6, a first source/drain layer 320 and a first conductive connection layer 340 may be sequentially formed on a second substrate 300.

In example embodiments, the first source/drain layer 320 may include or be formed of polysilicon doped with n-type impurities or p-type impurities, and the first conductive connection layer 340 may include or be formed of a metal or a metal nitride.

In example embodiments, when the first source/drain layer 320 is formed on the first conductive connection layer 340, a first ohmic contact layer 330 may be formed between the first source/drain layer 320 and the first conductive connection layer 340, or after forming the first conductive connection layer 340, an additional heat treatment process may be performed to form the first ohmic contact layer 330. The first ohmic contact layer 330 may include or be formed of silicide of a metal included in the first conductive connection layer 340.

A second bonding layer 360 may be formed on the first conductive connection layer 340.

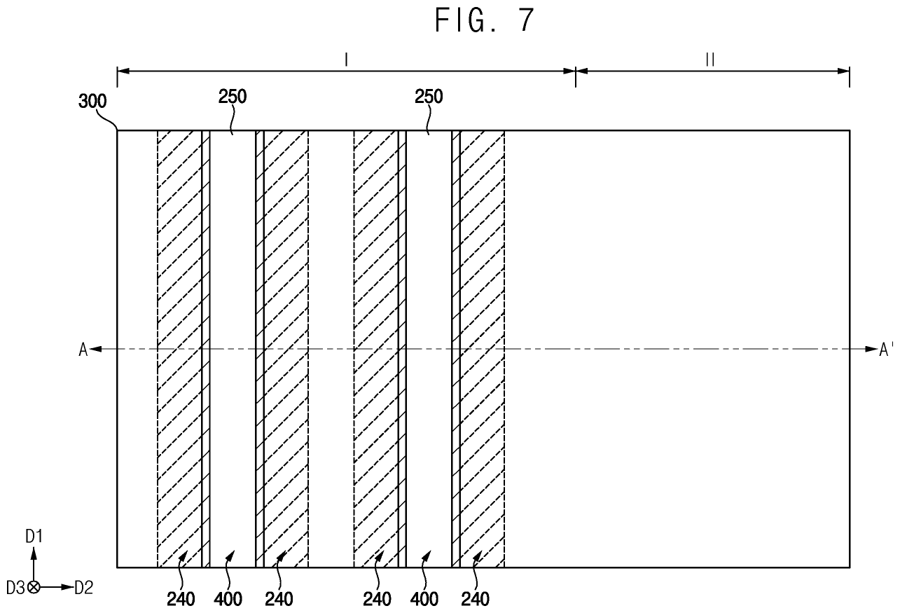

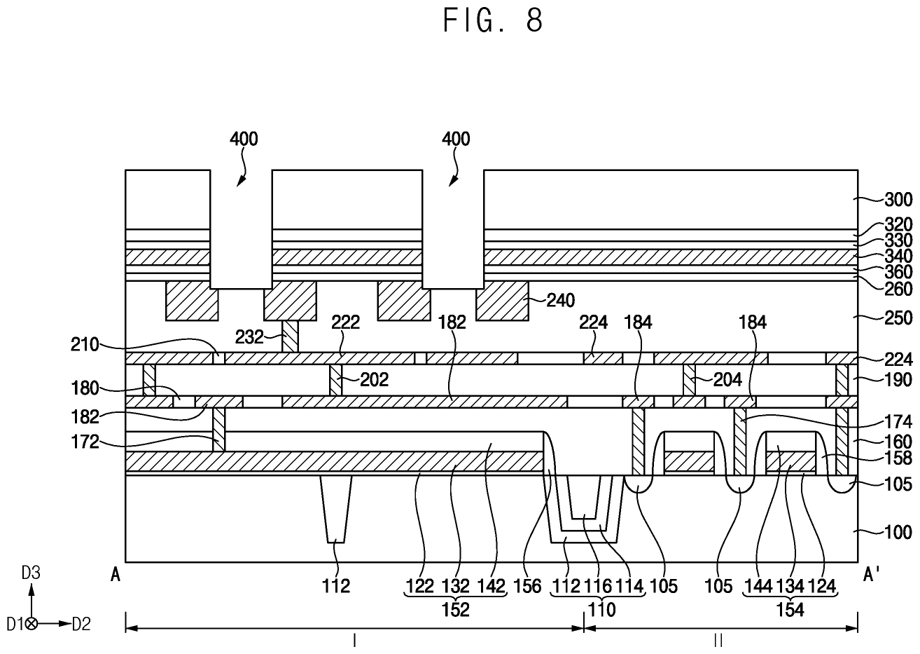

Referring to FIGS. 7 and 8, after overturning the second substrate 300, the first and second substrates 100 and 300 may be bonded with each other such that a lower surface of the second bonding layer 360 may contact an upper surface of the first bonding layer 260.

A first opening 400 may be formed through the second substrate 300, the first source/drain layer 320, the first ohmic contact layer 330, the first conductive connection layer 340, the second bonding layer and the first bonding layer 260 to partially expose an upper surface of the bit line 240.

In example embodiments, the first opening 400 may extend in the first direction D1 on the first region I and the portion of the second region II of the first substrate 100 adjacent to the first region I of the first substrate 100 in the first direction D1, and may expose an upper surface of a portion of the fifth insulating interlayer 250 between neighboring ones of the bit lines 240 in the second direction D2 and upper surfaces of edge portions of the neighboring ones of the bit lines 240 adjacent to the portion of the fifth insulating interlayer 250 in the second direction D2. In example embodiments, the first opening 400 may expose an upper surface of a portion of the fifth insulating interlayer 250 between neighboring ones of the bit lines 240 in the second direction D2 included in each bit line pair and upper surfaces of edge portions of the neighboring ones of the bit lines 240 in each bit line pair adjacent to the portion of the fifth insulating interlayer 250 in the second direction D2.

In an example embodiment, the first opening 400 may extend through an upper portion of the portion of the fifth insulating interlayer 250 and upper portions of the edge portions of the bit lines 240, however, the inventive concept is not limited thereto.

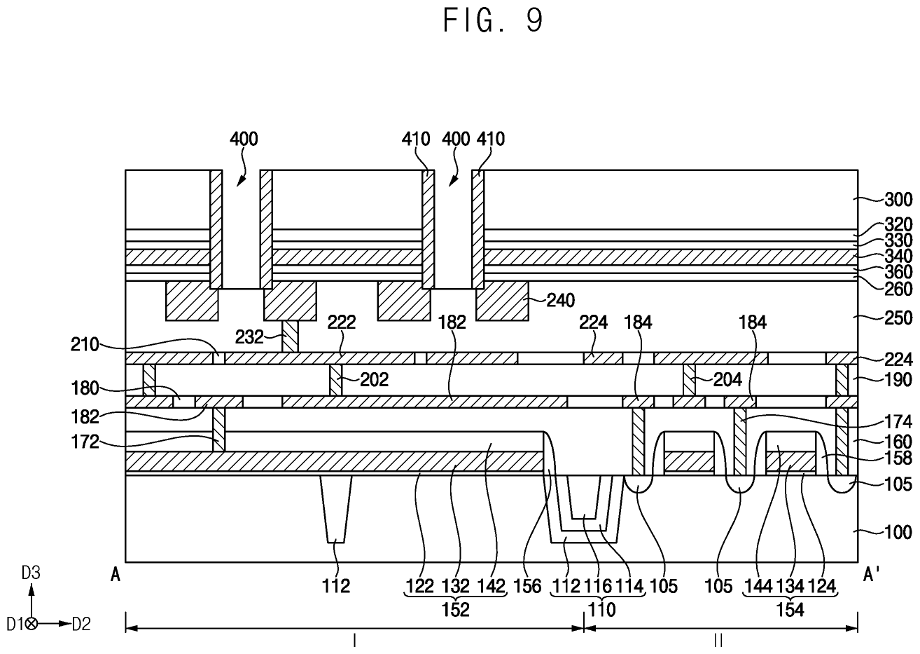

Referring to FIG. 9, a second conductive connection layer may be formed on the upper surface of the portion of the fifth insulating interlayer 250 and the upper surfaces of the edge portions of the bit lines 240 exposed by the first opening 400, a sidewall of the first opening 400 and an upper surface of the second substrate 300, and may be anisotropically etched to form a second conductive connection pattern 410 on the sidewall of the first opening 400.

In example embodiments, the second conductive connection pattern 410 may contact the upper surface of each of the edge portions of the bit lines 240 exposed by the first opening 400, and may also contact the upper surface of the portion of the fifth insulating interlayer 250 adjacent to the bit lines 240 in the second direction D2.

In example embodiments, the second conductive connection pattern 410 may extend lengthwise in the first direction D1, and a plurality of second conductive connection patterns 410 may be spaced apart from each other in the second direction D2. An item, layer, or portion of an item or layer described as extending “lengthwise” in a particular direction has a length in the particular direction and a width perpendicular to that direction, where the length is greater than the width.

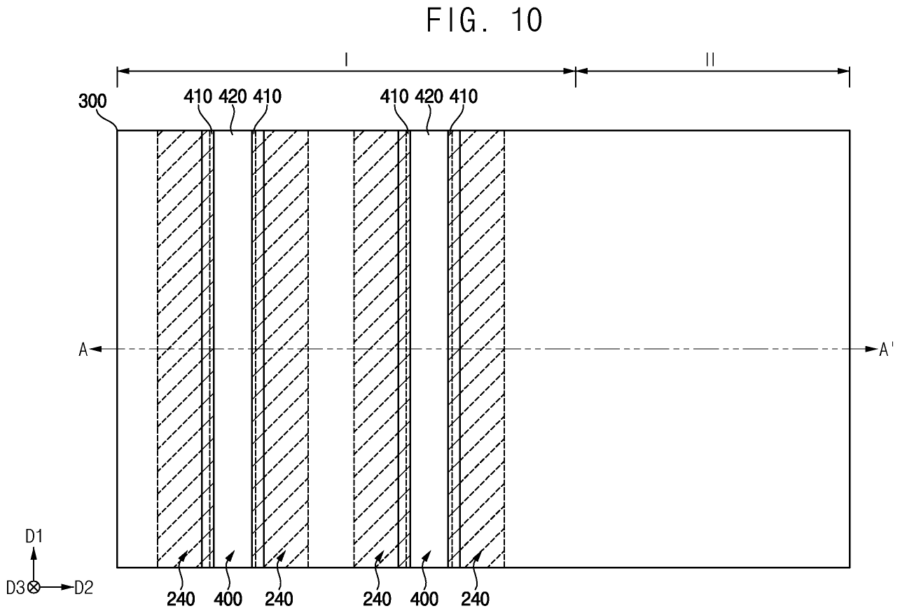

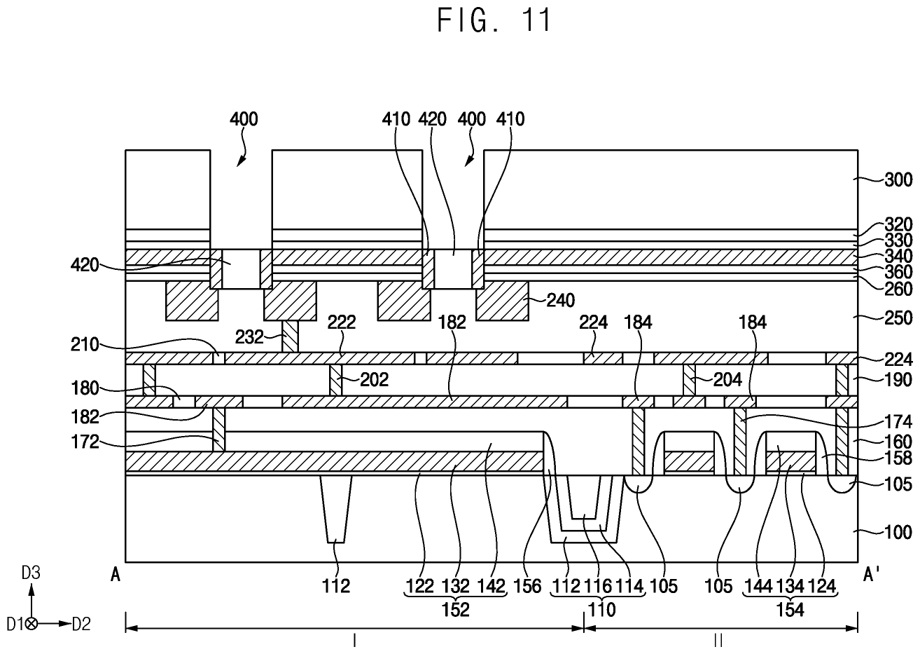

Referring to FIGS. 10 and 11, a first sacrificial layer may be formed in the first opening 400, and an upper portion of the first sacrificial layer may be removed to form a first sacrificial pattern 420 in a lower portion of the first opening 400.

In example embodiments, an upper surface of the first sacrificial pattern 420 may be higher than a lower surface of the first conductive connection layer 340, and may be lower than an upper surface of the first source/drain layer 320. In an example embodiment, the upper surface of the first sacrificial pattern 420 may be lower than a lower surface of the first source/drain layer 320. In one embodiment, the upper surface of the first sacrificial pattern 420 may be substantially coplanar with a lower surface of the first ohmic contact layer 330, which is shown in FIG. 11.

The first sacrificial pattern 420 may include or be formed of, e.g., spin-on-hardmask (SOH), amorphous carbon layer (ACL), etc.

An upper portion of the second conductive connection pattern 410 that is higher than the upper surface of the first sacrificial pattern 420 may be removed by an etching process so that an upper surface of the second conductive connection pattern 410 may be lowered to be substantially coplanar with the upper surface of the first sacrificial pattern 420. An upper portion (e.g., an upper sidewall portion) of the second conductive connection pattern 410 may contact a sidewall of the first conductive connection layer 340.

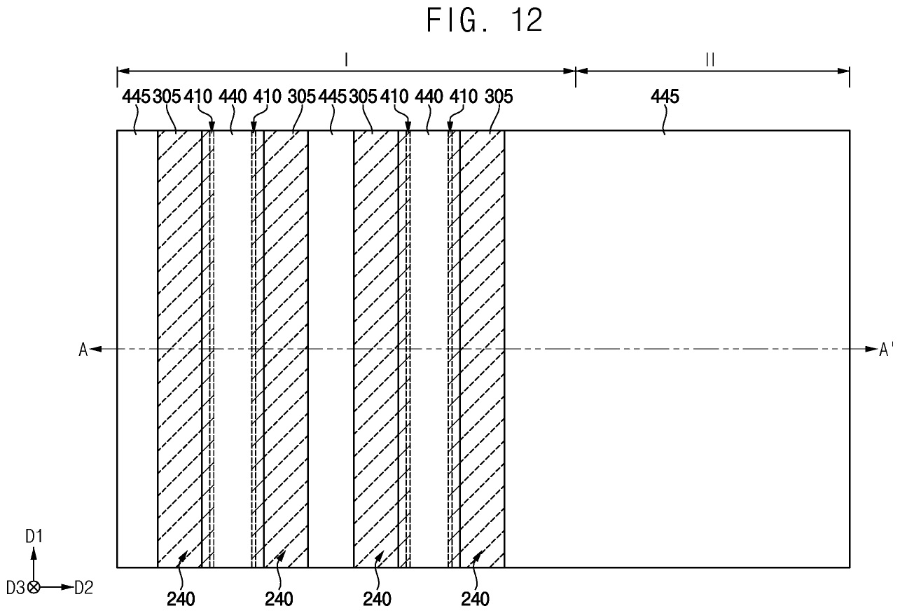

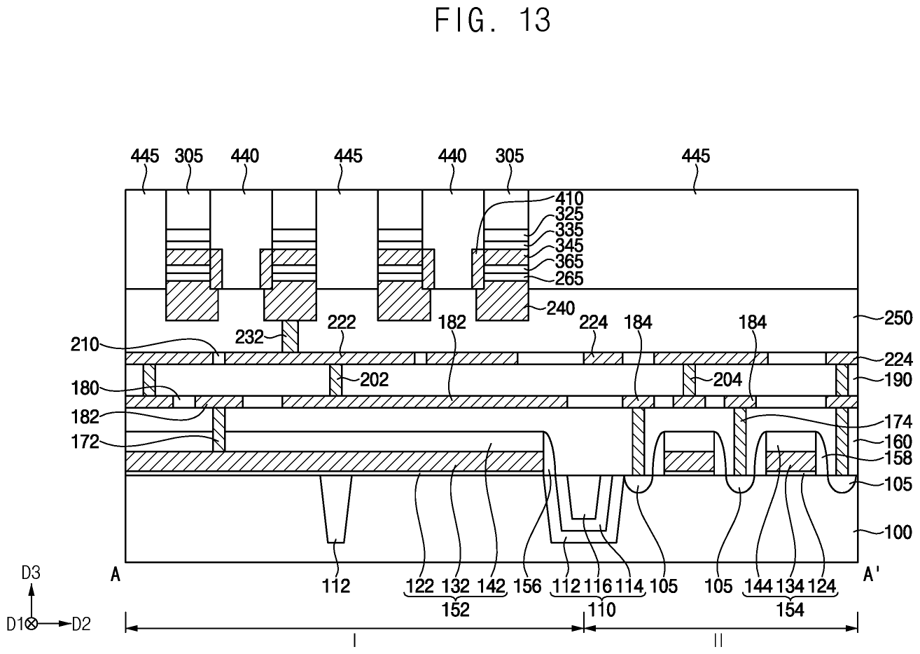

Referring to FIGS. 12 and 13, the first sacrificial pattern 420 may be removed by, e.g., an ashing process and/or a stripping process, and a sixth insulating interlayer 440 may be formed in the first opening 400.

A second opening may be formed through the second substrate 300, the first source/drain layer 320, the first ohmic contact layer 330, the first conductive connection layer 340, the second bonding layer and the first bonding layer 260 to expose an upper surface of the fifth insulating interlayer 250, and a seventh insulating interlayer 445 may be formed to fill the second opening.

In example embodiments, the second opening may expose an upper surface of a portion of the fifth insulating interlayer 250 that is between neighboring ones of the bit line pairs in the second direction D2. The second opening may also expose a portion of the fifth insulating interlayer 250 on the second region II of the first substrate 100.

Thus, each of the sixth and seventh insulating interlayers 440 and 445 may extend in the first direction D1, and the sixth and seventh insulating interlayers 440 and 445 may be alternately and repeatedly formed in the second direction D2.

As the second opening is formed, the second substrate 300, the first source/drain layer 320, the first ohmic contact layer 330, the first conductive connection layer 340, the second bonding layer 360 and the first bonding layer 260 may be transformed into a channel 305, a first source/drain pattern 325, a first ohmic contact pattern 335, a first conductive connection pattern 345, a second bonding pattern 365 and a first bonding pattern 265, respectively, each of which may extend in the first direction D1. The first and second bonding patterns 265 and 365, the first conductive pattern 345, the first ohmic contact pattern 335, the first source/drain pattern 325 and the channel 305 may be sequentially stacked in the third direction D3 on each of the bit lines 240 spaced apart from each other in the second direction D2.

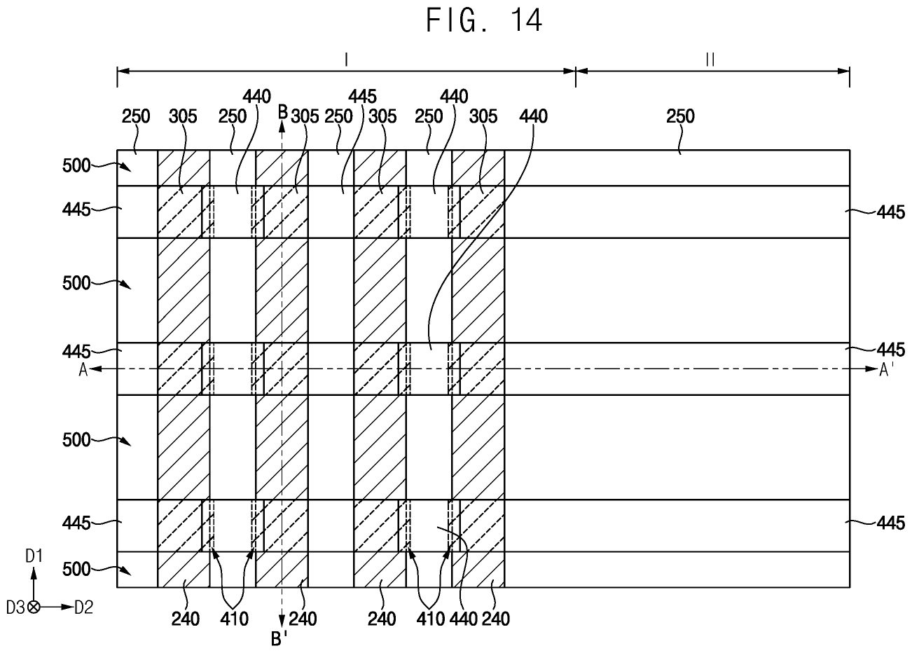

Referring to FIGS. 14 and 15, an etching mask may be formed on the sixth and seventh insulating interlayers 440 and 445 and the channel 305, and the sixth and seventh insulating interlayers 440 and 445, the channel 305, the first source/drain pattern 325, the first ohmic contact pattern 335, the first conductive connection pattern 345, the second bonding pattern 365 and the first bonding pattern 265 may be patterned by an etching process using the etching mask, and thus a third opening 500 may be formed to expose upper surfaces of the bit line 240 and the fifth insulating interlayer 250.

In example embodiments, the third opening 500 may extend in the second direction D2 on the first region I of the first substrate 100 and the portion of the second region II of the first substrate 100 adjacent thereto, and a plurality of third openings 500 may be spaced apart from each other in the first direction D1.

As the third opening 500 is formed, each of the first and second bonding patterns 265 and 365, the first conductive pattern 345, the first ohmic contact pattern 335, the first source/drain pattern 325 and the channel 305 may be divided into a plurality of parts spaced apart from each other in the first direction D1 on each of the bit lines 240. Additionally, each of the sixth and seventh insulating interlayers 440 and 445 may be divided into a plurality of parts spaced apart from each other in the first direction D1.

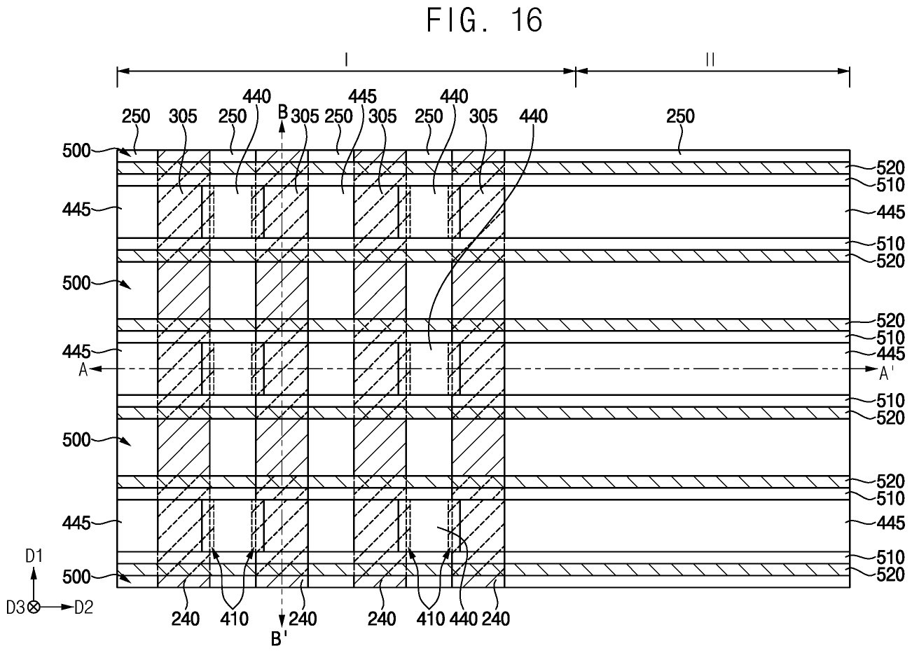

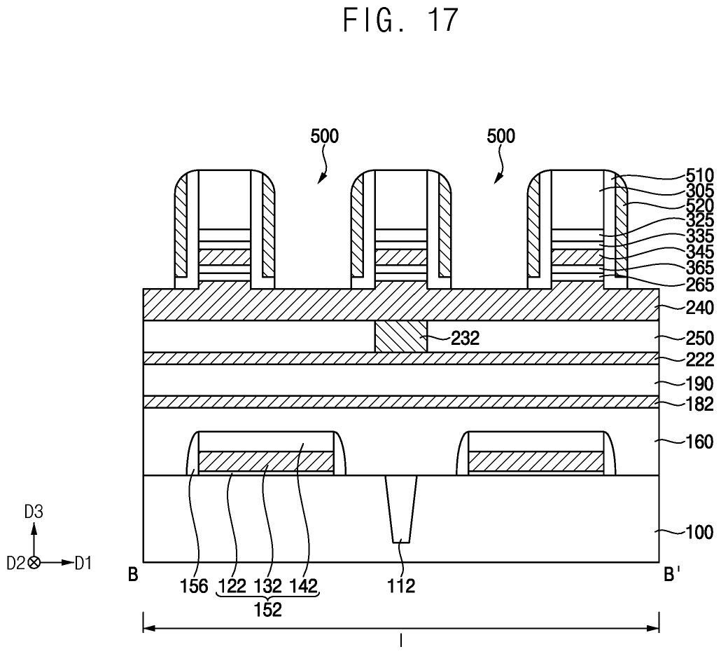

Referring to FIGS. 16 and 17, a third gate insulation layer and a third gate electrode layer may be sequentially formed on the upper surfaces of the bit line 240 and the fifth insulating interlayer 250 exposed by the third opening 500, a sidewall of the third opening 500, and upper surfaces of the channel 305 and the sixth and seventh insulating interlayers 440 and 445, and may be anisotropically etched to form a third gate insulation pattern 510 and a third gate electrode 520, respectively, on the sidewall of the third opening 500.

Each of the third gate insulation pattern 510 and the third gate electrode 520 may extend in the second direction D2. A plurality of third gate insulation patterns 510 may be spaced apart from each other in the first direction D1, and a plurality of third gate electrodes 520 may be spaced apart from each other in the first direction D1.

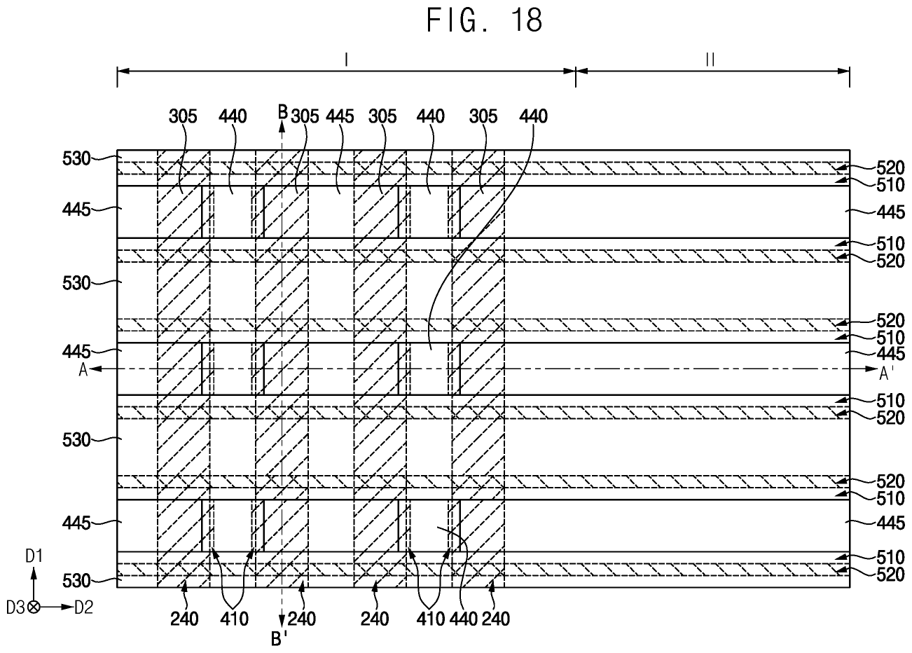

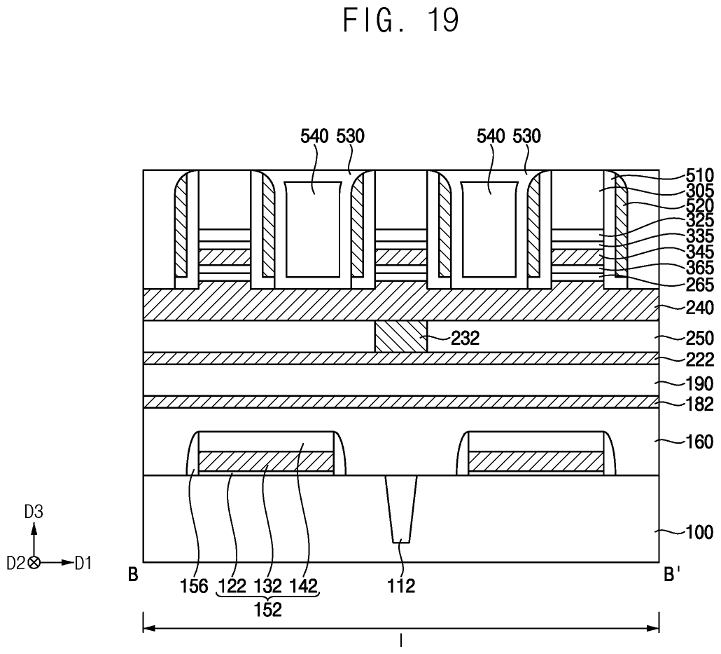

Referring to FIGS. 18 and 19, a first insulation layer may be formed on the upper surfaces of the bit line 240 and the fifth insulating interlayer 250 exposed by the third opening 500, sidewalls and upper surfaces of the third gate electrode 520 and the third gate insulation pattern 510, and the upper surfaces of the channel 305 and the sixth and seventh insulating interlayers 440 and 445, an eighth insulating interlayer may be formed on the first insulation layer to fill the third opening 500, and a planarization process may be performed on the eighth insulating interlayer and the first insulation layer until the upper surfaces of the channel 305 and the sixth and seventh insulating interlayers 440 and 445 are exposed.

In example embodiments, the planarization process may include a chemical mechanical polishing (CMP) process and/or an etch back process. As the planarization process is formed, the eighth insulating interlayer and the first insulation layer may remain as an eighth insulating interlayer pattern 540 and a first insulation pattern 530, respectively, in the third opening 500, and each of the first insulation pattern 530 and the eighth insulating interlayer pattern 540 may extend in the second direction D2 on the bit line 240 and the fifth insulating interlayer 250.

An upper portion of the eighth insulating interlayer pattern 540 may be removed to form a recess, and a second insulation pattern may be further formed in the recess. In an example embodiment, the second insulation pattern may include substantially the same material as the first insulation pattern 530 to be merged thereto. Hereinafter, the first insulation pattern 530 and the second insulation pattern merged thereto may be collectively referred to as the first insulation pattern 530.

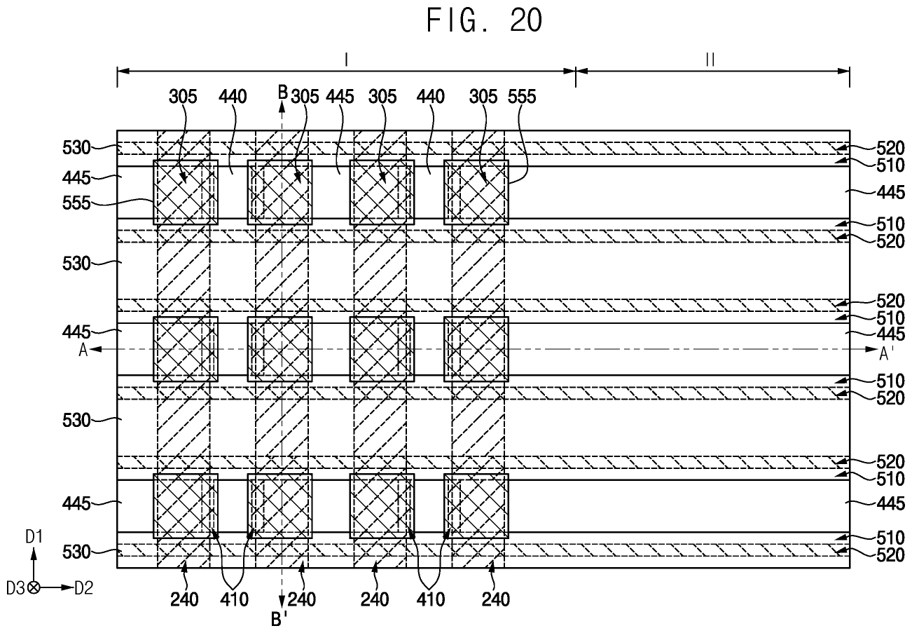

Referring to FIGS. 20 to 22, a second source/drain pattern 550 and a landing pad 555 may be formed on the channel 305.

The second source/drain pattern 550 and the landing pad 555 may be formed by sequentially forming a second source/drain layer and a landing pad layer on the channel 305, the sixth and seventh insulating interlayers 440 and 445 and the first insulation pattern 530, and patterning the second source/drain layer and the landing pad layer.

In example embodiments, a plurality of second source/drain patterns 550 may be spaced apart from each other in the first and second directions D1 and D2 on the first region I of the first substrate 100, and a plurality of landing pads 555 may be spaced apart from each other in the first and second directions D1 and D2 on the first region I of the first substrate 100. The second source/drain patterns 550 may contact upper surfaces of corresponding ones of the channels 305, respectively. In an example embodiment, the landing pads 555 may be arranged in a lattice pattern. Alternatively, the landing pads 555 may be arranged in a honeycomb pattern.

Referring to FIGS. 1 to 3 again, a ninth insulating interlayer may be formed on the first insulation pattern 530, the channel 305 and the sixth and seventh insulating interlayers 440 and 445 to cover the second source/drain pattern 550 and the landing pad 555, and may be planarized until an upper surface of the landing pad 555 is exposed. Thus, a ninth insulating interlayer pattern 560 may be formed to cover the second source/drain pattern 550 and the landing pad 555.

A first capacitor electrode 570 may be formed to contact the upper surface of the landing pad 555, a dielectric layer 580 may be formed on an upper surface and a sidewall of the first capacitor electrode 570 and an upper surface of the ninth insulating interlayer pattern 560, and a second capacitor electrode 590 may be formed on the dielectric layer 580 to form a capacitor 600.

Thus, the fabrication of the semiconductor device may be completed.

As illustrated above, the lower circuit pattern and the bit line 240 may be formed on the first substrate 100, the first conductive connection layer 340 may be formed on the second substrate 300, and the first and second substrates 100 and 300 may be bonded with each other such that the first and second bonding layers 260 and 360 contact each other.

The first opening 400 may be formed through the second substrate 300, the first conductive connection layer 340, and the first and second bonding layers 260 and 360 to expose the upper surface of the bit line 240, the second conductive connection pattern 410 may be formed on the sidewall of the first opening 400 to contact the bit line 240 and the first conductive connection layer 340, and the second substrate 300, the first conductive connection layer 340 and the first and second bonding layers 260 and 360 may be patterned to form the channel 305, the first conductive connection pattern 345 and the first and second bonding patterns 265 and 365.

Instead of forming the bit line 240 on the second substrate 300 and bonding the first and second substrates 100 and 300 so that the bit line 240 and transistors on the first substrate 100 are electrically connected to each other, the bit line 240 may be directly formed on the transistors on the first substrate 100. Thus, misalignment between the bit line 240 and the transistor may not occur, and thus an additional pad having a large area for compensating the misalignment is not needed. Accordingly, the semiconductor device may have an enhanced integration degree.

The bit line 240 on the first substrate 100 and the channel 305 that may be formed by patterning the second substrate 300 may be electrically connected to each other through the first and second conductive connection patterns 345 and 410. The first conductive connection pattern 345 may be formed by forming the first conductive connection layer 340 on the second substrate 300 and patterning the first conductive connection layer 340, and the second conductive connection pattern 410 may be formed on the sidewall of the first opening 400 that may be formed by patterning the second substrate 300 and the first conductive connection layer 340 to expose the upper surface of the bit line 240. Thus, the first and second conductive connection patterns 345 and 410, which may electrically connect the channel 305 and the bit line 240 to each other, may be formed to contact the channel 305 and the bit line 240, respectively.

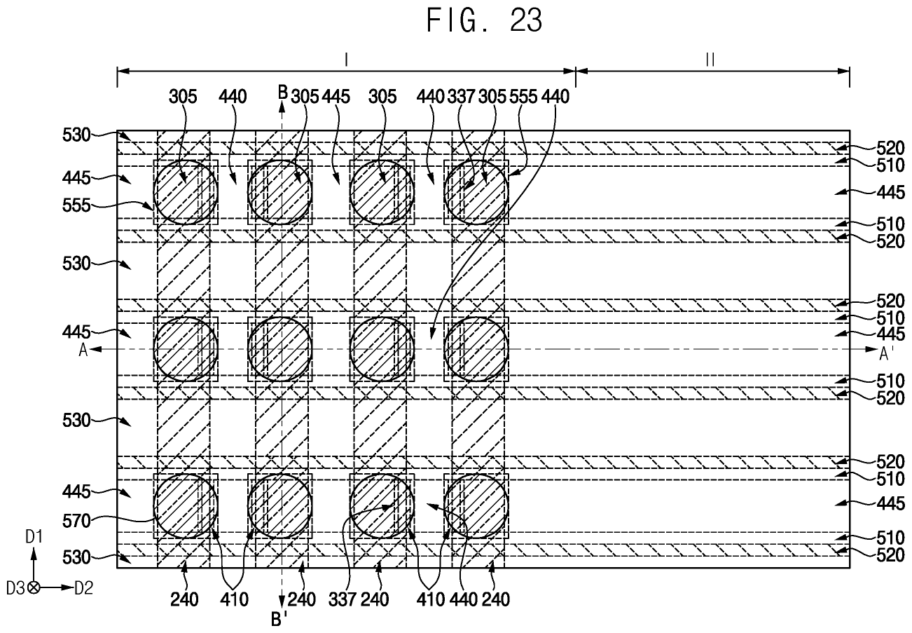

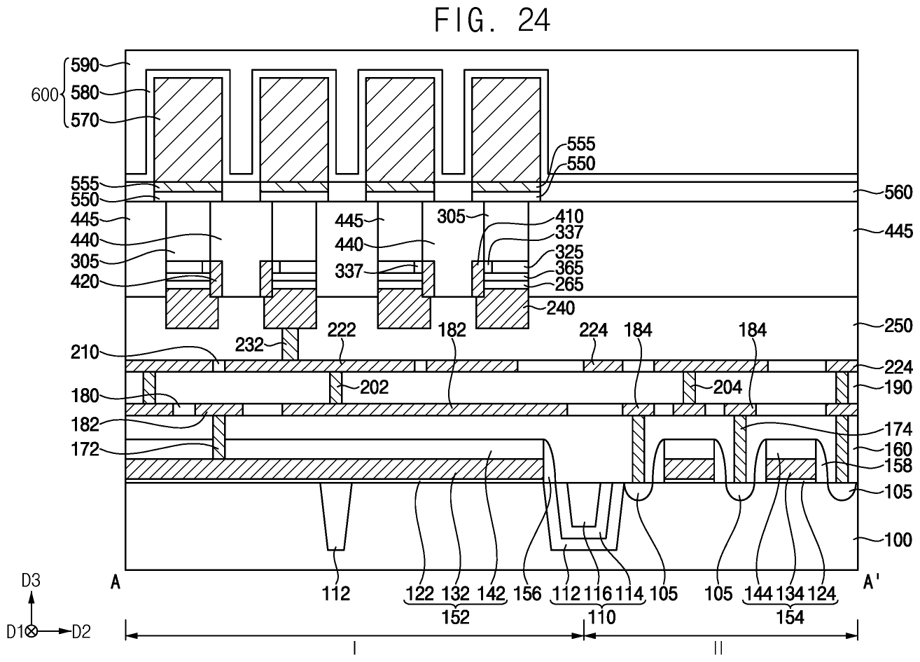

FIGS. 23 and 24 are a plan view and a cross-sectional view illustrating a semiconductor device in accordance with example embodiments, which may correspond to FIGS. 1 and 2, respectively. This semiconductor device may be substantially the same as or similar to that of FIGS. 1 to 3, except for some elements, and thus repeated explanations are omitted herein.

Referring to FIGS. 23 and 24, the semiconductor device may not include the first conductive connection pattern 345 and the first ohmic contact pattern 335 on the bonding structure, and the first source/drain pattern 325 may contact an upper surface of the bonding structure.

In example embodiments, a second ohmic contact pattern 337 may be formed on a sidewall of the first source/drain pattern 325, and a sidewall of the second ohmic contact pattern 337 may contact the second conductive connection pattern 410. Additionally, the channel 305 may contact an upper surface of the second ohmic contact pattern 337.

In an example embodiment, the second ohmic contact pattern 337 may include or be formed of silicide of a metal included in the second conductive connection pattern 410.

In example embodiments, an upper surface of the second conductive connection pattern 410 may be higher than a lower surface of the second ohmic contact pattern 337. In an example embodiment, the upper surface of the second conductive connection pattern 410 may be substantially coplanar with an upper surface of the second ohmic contact pattern 337, which is shown in FIG. 24.

In the semiconductor device, the channel 305 and the bit line 240 may be electrically connected to each other through the first source/drain pattern 325, the second ohmic contact pattern 337, and the second conductive connection pattern 410. In both the embodiment of FIGS. 1-3 and the embodiment of FIGS. 23-24, the bit line 240 is electrically connected to a conductive pattern (e.g., first connection pattern 345 in FIGS. 1-3 and second ohmic contact pattern 337 in FIGS. 23-24) vertically separated therefrom by an electrically insulating layer, by second connection pattern 410.

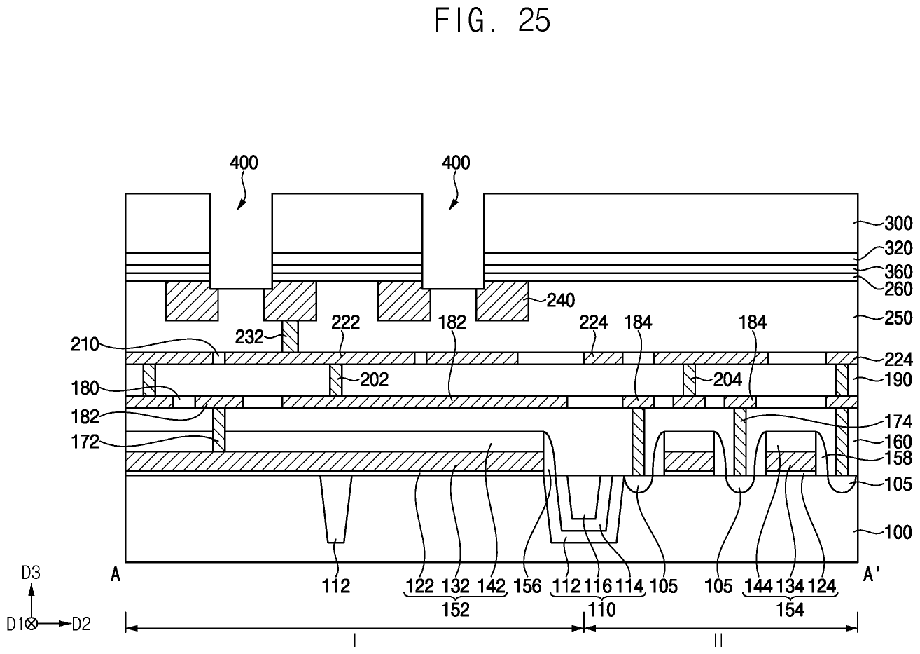

FIGS. 25 to 28 are cross-sectional views illustrating a method of manufacturing a semiconductor device in accordance with example embodiments, which are cross-sectional views taken along lines A-A′ of corresponding plan views, respectively.

This method may include processes substantially the same as or similar to those illustrated with respect to FIGS. 4 to 22 and FIGS. 1 to 3, and thus repeated explanations thereof are omitted herein.

Referring to FIG. 25, processes substantially the same as or similar to those illustrated with respect to FIGS. 4 to 8 are performed.

However, only the first source/drain layer 320 and the second bonding layer 360 are formed on the second substrate 300, and the first ohmic contact layer 330 and the first conductive connection layer 340 are not formed on the second substrate 300.

Thus, the first opening 400 is formed through the second substrate 300, the first source/drain layer 320 and the second bonding layer 360.

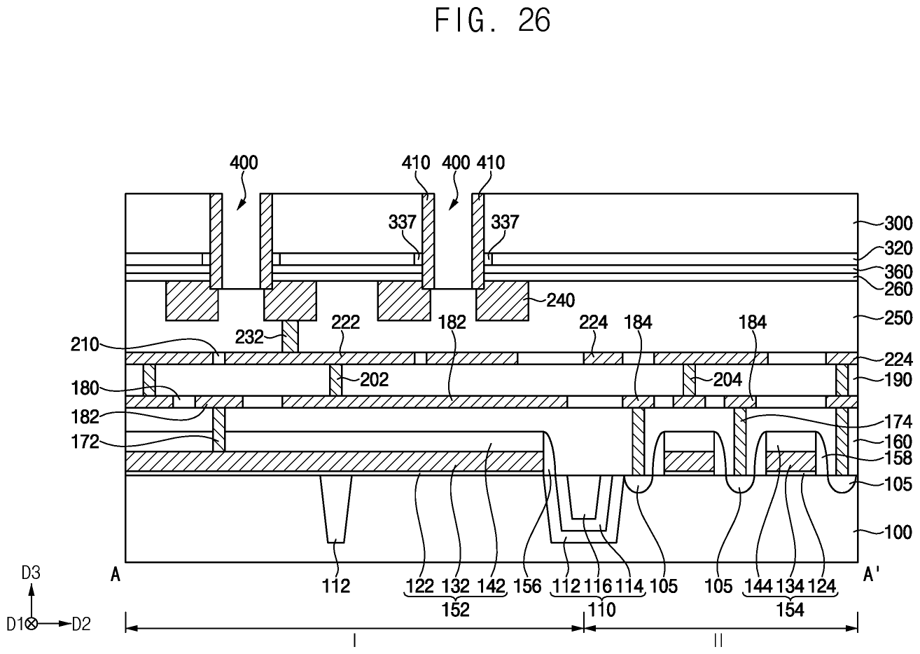

Referring to FIG. 26, processes substantially the same as or similar to those illustrated with respect to FIG. 9 are performed so that the second conductive connection pattern 410 may be formed on the sidewall of the first opening 400.

In example embodiments, when the second conductive connection pattern 410 is formed, an additional heat treatment process may be performed, and thus a second ohmic contact pattern 337 including a metal silicide may be formed on a sidewall of the first source/drain layer 320 contacting the second conductive connection pattern 410.

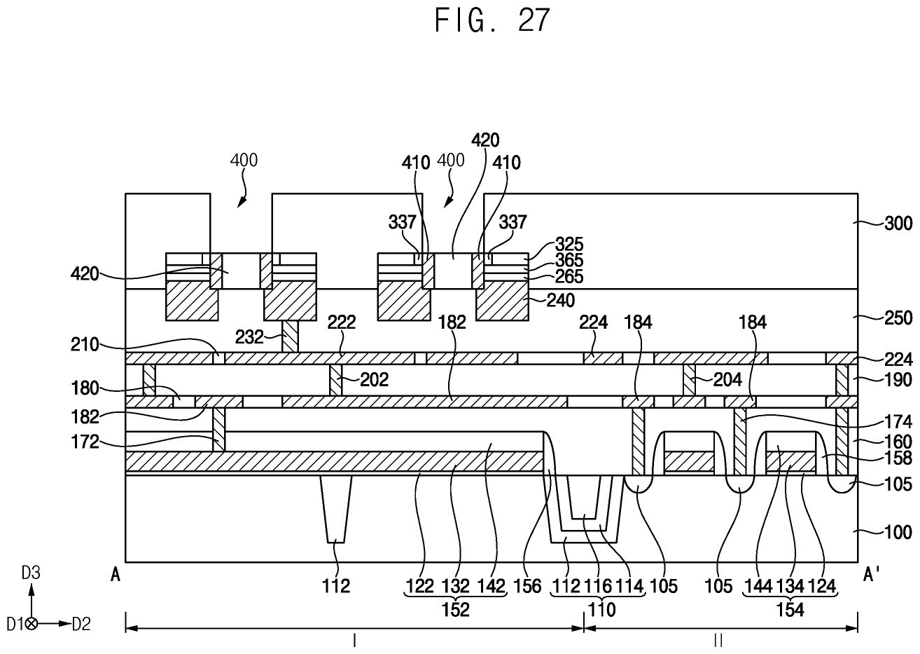

Referring to FIG. 27, processes substantially the same as or similar to those illustrated with respect to FIGS. 10 and 11 are performed to form a first sacrificial pattern 420 in a lower portion of the first opening 400, and an upper portion of the second conductive connection pattern 410 at a level higher than the upper surface of the first sacrificial pattern 420 may be removed. In example embodiments, the upper surfaces of the first sacrificial pattern 420 and the second conductive connection pattern 410 may be higher than a lower surface of the second ohmic contact pattern 337. In an example embodiment, the upper surfaces of the first sacrificial pattern 420 and the second conductive connection pattern 410 may be substantially coplanar with an upper surface of the second ohmic contact pattern 337, which is shown in FIG. 27. An upper portion of the second conductive connection pattern 410 may contact a sidewall of the second ohmic contact pattern 337.

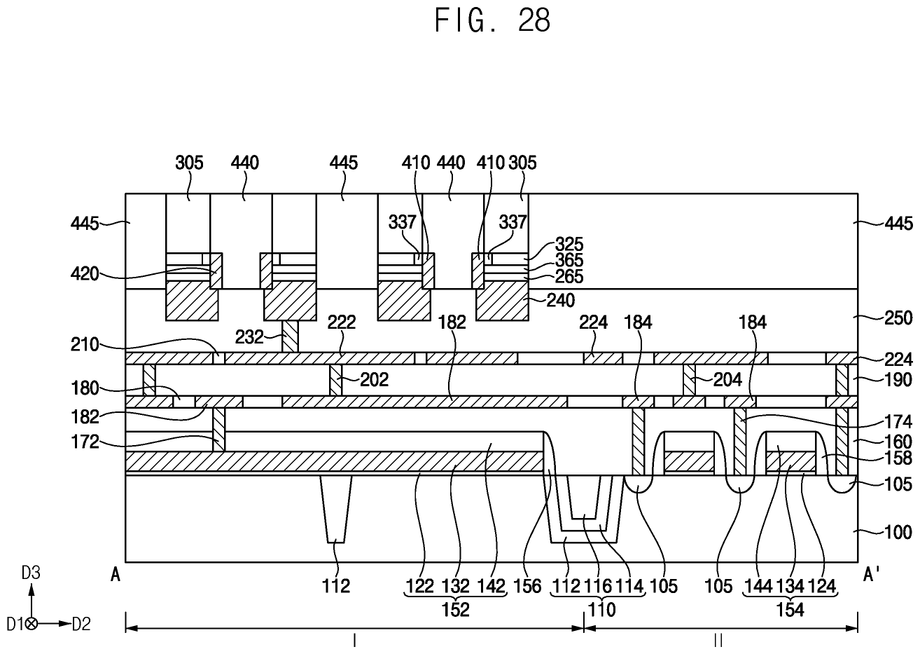

Referring to FIG. 28, processes substantially the same as or similar to those illustrated with respect to FIGS. 12 and 13 may be performed to form the sixth and seventh insulating interlayers 440 and 445.

Referring to FIGS. 23 and 24 again, processes substantially the same as or similar to those illustrated with respect to FIGS. 14 to 22 and FIGS. 1 to 3 may be performed to complete the fabrication of the semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and that modifications to the disclosed example embodiments, as well as other example embodiments, are intended to be included within the scope of the appended claims.

1. A semiconductor device comprising:
a bit line on a substrate;
a bonding layer stacked on the bit line;
a first conductive connection pattern stacked on the bonding layer, so that the bonding layer is vertically between the bit line and the first conductive connection pattern;
a channel stacked on the first conductive connection pattern, the channel including a single crystalline semiconductor material;
a second conductive connection pattern contacting the bit line and the first conductive connection pattern;
a gate electrode on the bit line, the gate electrode being spaced apart from the channel and the first conductive connection pattern; and
a capacitor stacked on the channel.

2. The semiconductor device according to claim 1, wherein the second conductive connection pattern contacts an upper surface of the bit line and a sidewall of the first conductive connection pattern.

3. The semiconductor device according to claim 2, wherein the bonding layer is formed of an insulative material.

4. The semiconductor device according to claim 1, wherein a sidewall of the second conductive connection pattern is aligned with a sidewall of the channel in a vertical direction perpendicular to an upper surface of the substrate.

5. The semiconductor device according to claim 1, wherein the bit line is one of a plurality of bit lines spaced apart from each other in a second direction parallel to an upper surface of the substrate, each of the plurality of bit lines extending in a first direction parallel to the upper surface of the substrate and crossing the second direction and connected to a respective bonding layer and a respective second conductive connection pattern,
wherein two bit lines of the plurality of bit lines neighboring in the second direction form a bit line pair, and a plurality of bit line pairs are arranged in the second direction, and
wherein for each bit line pair, a first sidewall of a first bit line faces a second sidewall of a second bit line, one second conductive connection pattern is disposed on the first sidewall of the first bit line, and another second conductive connection pattern is disposed on the second sidewall of the second bit line.

6. The semiconductor device according to claim 1, further comprising a source/drain pattern between the first conductive connection pattern and the channel, the source/drain pattern including doped polysilicon.

7. The semiconductor device according to claim 1, further comprising a source/drain pattern and a landing pad stacked between the channel and the capacitor.

8. The semiconductor device according to claim 1, wherein the first conductive connection pattern includes a metal, and
wherein the semiconductor device further comprises an ohmic contact pattern between the first conductive connection pattern and the channel, the ohmic contact pattern including a metal silicide.

9. The semiconductor device according to claim 1, wherein the bonding layer includes silicon carbonitride.

10. A semiconductor device comprising:
a bit line on a substrate;
an insulative bonding layer stacked on the bit line;
a first source/drain pattern stacked on the bonding layer, so that the bonding layer is between the bit line and the first source/drain pattern, the first source/drain pattern including doped polysilicon;
a channel on the first source/drain pattern, the channel including a single crystalline semiconductor material;
a conductive pattern vertically between the channel and the bonding layer;
a conductive connection pattern contacting the bit line and the conductive pattern;
a gate electrode on the bit line, the gate electrode being spaced apart from the channel and the conductive pattern; and
a capacitor on the channel.

11. The semiconductor device according to claim 10, wherein the conductive pattern is an ohmic contact pattern contacting a sidewall of the first source/drain pattern, the ohmic contact pattern including a metal silicide;

12. The semiconductor device according to claim 11, wherein the channel contacts an upper surface of the ohmic contact pattern.

13. The semiconductor device according to claim 11, wherein a sidewall of the conductive connection pattern is aligned with a sidewall of the channel in a vertical direction perpendicular to an upper surface of the substrate.

14. The semiconductor device according to claim 9, wherein the bit line is one of a plurality of bit lines spaced apart from each other in a second direction parallel to an upper surface of the substrate, each of the plurality of bit lines extending in a first direction parallel to the upper surface of the substrate and crossing the second direction,
wherein two bit lines of the plurality of bit lines neighboring in the second direction form a bit line pair, and a plurality of bit line pairs are arranged in the second direction, and
wherein for each bit line pair, a first sidewall of a first bit line faces a second sidewall of a second bit line, one conductive connection pattern is disposed on the first sidewall of the first bit line, and another conductive connection pattern is disposed on the second sidewall of the second bit line.

15. The semiconductor device according to claim 11, further comprising a second source/drain pattern and a landing pad stacked between the channel and the capacitor.

16. The semiconductor device according to claim 11, wherein the conductive connection pattern includes a metal.

17. The semiconductor device according to claim 11, wherein the bonding structure includes silicon carbonitride.

18. A semiconductor device comprising:
a lower circuit pattern on a substrate;
bit lines on the lower circuit pattern, each of the bit lines extending in a first direction parallel to an upper surface of the substrate, and the bit lines being spaced apart from each other in a second direction parallel to the upper surface of the substrate and crossing the first direction;
bonding structures on the bit lines, respectively;
a plurality of first conductive connection patterns, each first conductive connection pattern on a respective bonding structure;
a plurality of first source/drain patterns, each first source/drain pattern on a respective first conductive connection pattern;
a plurality of channels, each channel on a respective first source/drain pattern;
a plurality of second conductive connection patterns, each second conductive connection pattern contacting a respective bit line of the bit lines and a respective first conductive pattern of the plurality of first conductive connection patterns;
a plurality of gate electrodes, each gate electrode on a respective bit line, each of the gate electrodes extending in the second direction, and the gate electrodes being spaced apart from each other in the first direction;
a gate insulation pattern on a sidewall of each of the gate electrodes and contacting each of the channels;
a plurality of second source/drain patterns, each second source/drain pattern on a respective channel;
a plurality of landing pads, each landing pad on a respective second source/drain pattern; and
a plurality of capacitors, each capacitor on a respective landing pad.

19. The semiconductor device according to claim 17, wherein two bit lines of the bit lines neighboring in the second direction form a bit line pair, and a plurality of bit line pairs are arranged in the second direction, and
wherein for each bit line pair, a first sidewall of a first bit line faces a second sidewall of a second bit line, one second conductive connection pattern is disposed on the first sidewall of the first bit line, and another second conductive connection pattern is disposed on the second sidewall of the second bit line.

20. The semiconductor device according to claim 18, wherein the gate insulation pattern contacts sidewalls in the first direction of each of the bonding structures and the first conductive connection pattern and the first source/drain pattern on each of the bonding structures.

21-22. (canceled)
